(19) United States
(12) Patent Application Publication
(10) Pub. No.: US 2026/0082992 A1
(43) Pub. Date: Mar. 19, 2026

(54) PRESS CONTACT TYPE SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Daiki WATANABE, Himeji Hyogo (JP); Shigeaki HAYASE, Himeji Hyogo (JP)

(21) Appl. No.: 19/070,408

(22) Filed: Mar. 4, 2025

(30) Foreign Application Priority Data
Sep. 19, 2024 (JP) 2024-162669

(51) Int. Cl. H01L 23/10; H01L 23/06; H01L 23/24; H01L 25/07

(52) U.S. Cl. CPC H10W 76/60; H10W 76/17; H10W 76/47; H10W 90/00

(57) ABSTRACT

According to one embodiment, a press contact type semiconductor device includes a first electrode, a second electrode, a pair of metal plates arranged between the first electrode and the second electrode, and a semiconductor element positioned between the pair of metal plates. The semiconductor element includes a semiconductor part with an electrode part on the upper surface of the semiconductor part. A metal sintered layer is between one of the metal plates and the electrode part. The surface area of the electrode part is less than the surface area of the metal plate.

### CROSS-REFERENCE TO RELATED APPLICATION(S)

This application is based upon and claims the benefit of priority from Japanese Patent Application No. 2024-162669, filed Sep. 19, 2024, the entire contents of which are incorporated herein by reference.

### FIELD

Embodiments described herein relate generally to a press contact type semiconductor device.

### BACKGROUND

There is a known press contact type semiconductor device which has improved power density by utilizing heat radiation from front and back surfaces. Such a device provides high reliability in high voltage and high current operation. Such a press contact type semiconductor device has a structure in which a plurality of semiconductor elements are provided inside an insulating frame that is sandwiched between upper and lower electrode blocks and hermetically sealed.

### BRIEF DESCRIPTION OF THE DRAWINGS

FIG. 1 is a cut-away perspective view of a semiconductor device according to an embodiment.

FIG. 2 is a schematic cross-sectional view of a part of a semiconductor device according to an embodiment.

FIG. 3 is an enlarged view of region D depicted in FIG. 2.

FIG. 4 is an enlarged view of region D in a semiconductor device according to a first modification.

FIG. 5 is an enlarged view of region D in a semiconductor device according to a second modification.

### DETAILED DESCRIPTION

Embodiments describe a press contact type semiconductor device having improved reliability.

In general, according to one embodiment, a press contact type semiconductor device includes a first electrode, a second electrode spaced from the first electrode in a first direction, a first metal plate between the first electrode and the second electrode in the first direction, a second metal plate between the first electrode and the second electrode in the first direction, and a semiconductor element between the first and second metal plates in the first direction. The semiconductor element has a semiconductor part with an electrode part on a first surface of the semiconductor part facing towards a second surface of the first metal plate. A metal sintered layer is between the first metal plate and the electrode part in the first direction. A planar surface area of a surface of the electrode part facing the first metal plate is less than a planar surface area of the second surface of the first metal plate.

Hereinafter, certain example embodiments according to the present disclosure will be described with reference to the drawings.

The drawings are schematic and conceptual, and depicted relationships between dimensions, such as thickness or widths, of each component and the ratios in sizes of the components are not necessarily the same as in an actual device. In addition, the dimensions and relative sizes of components may be differently illustrated in the different drawings.

In the specification and the drawings, reference symbols are allotted the same or substantially similar elements. Elements previously described in relation to a previous drawing, may be omitted as appropriate from description of subsequent drawings.

In the following description, the direction from the center of the semiconductor device 1 toward the outer periphery in a plan view is referred to as a radial direction. A direction from the second electrode 15 toward the first electrode 10 is referred to as “up”, and the opposite direction is referred to as “down”. These directions are based on the relative positional relationship between the first electrode 10 and the second electrode 15, the direction of gravity is irrelevant to such description.

### First Embodiment

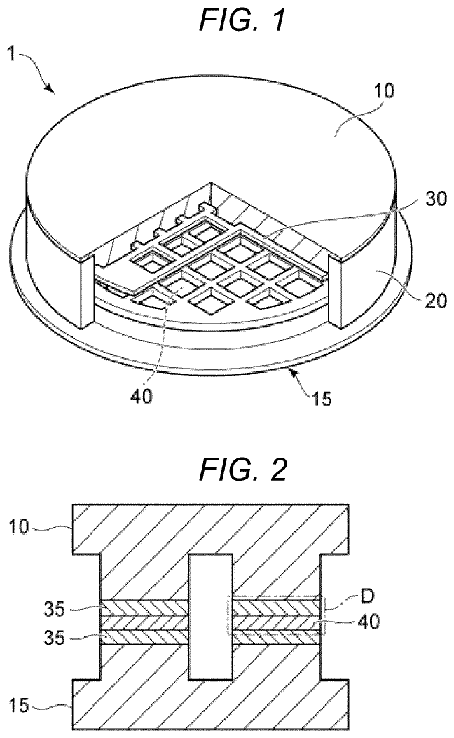

FIG. 1 is a cut-away perspective view of a semiconductor device according to an embodiment.

FIG. 2 is a schematic cross-sectional view of a part of a semiconductor device.

In FIGS. 1 and 2, the semiconductor device 1 according to the present embodiment is an injection enhanced gate transistor (IEGT), which is one example of a press contact type semiconductor device. In the present embodiment, the semiconductor device 1 may also be referred to as a press pack IEGT (PPI). In the press description, an IEGT is an insulated gate bipolar transistor (IGBT) having an electron injection promoting effect. The semiconductor device 1 includes a first electrode 10, a second electrode 15, a housing 20, a resin frame 30, a pair of metal plates 35, and a semiconductor element 40.

The first electrode 10 is provided on what is referred to as the upper surface side of the semiconductor device 1. The second electrode 15 is provided on what is referred toa as the lower surface side of the semiconductor device 1. The first electrode 10 and the second electrode 15 have, for example, a columnar or disc shape. The first electrode 10 and the second electrode 15 are formed of a metal, for example, copper.

The housing 20 has, for example, a cylindrical shape. The inner diameter of the housing 20 is, for example, 80 mm or more. The radial thickness of the housing 20 is, for example, between 4 mm and 20 mm. The housing 20 is made of, for example, alumina. In other examples, silicon nitride, zirconia, aluminum nitride, or the like may be used for the housing 20.

The resin frame 30 is formed of resin and is provided inside the housing 20. At least a portion of the resin frame 30 is provided between the first electrode 10 and the second electrode 15. The resin frame 30 is formed in a lattice shape in a plan view and holds a semiconductor element 40 in each rectangle (space) of the lattice. The resin frame 30 has a function of ensuring the insulation distance between the plurality of semiconductor elements 40 is maintained. The resin frame 30 also serves to align the plurality of semiconductor elements 40.

A pair of metal plates 35 is disposed between the first electrode 10 and the second electrode 15 so as to sandwich each semiconductor element 40 therebetween. The pair of metal plates 35 is preferably made of a metal having high heat resistance and high pressure resistance. For example, the metal plates 35 are each a molybdenum plate.

Each semiconductor element 40 is disposed between a pair of metal plates 35. In the present embodiment, the semiconductor element 40 is an IEGT, but is not necessarily limited to such a device type. In general, as long as semiconductor element 40 is a device including electrodes on the upper and lower sides thereof, it may be adopted in an embodiment. For example, semiconductor device 40 may be a diode, such as a fast recovery diode (FRD), or a MOSFET (Metal Oxide Semiconductor Field Effect Transistor) may be used. In some examples, a mix of IEGTs and FRDs may be used as the semiconductor devices 40. In other examples, the semiconductor device 40 may be an RC-IEGT (Reverse Conductive-IEGT) in which a diode and a IEGT are integrated into one chip. Furthermore, the semiconductor device 40 is not limited to a silicon device, and may be a silicon carbide (SiC) device.

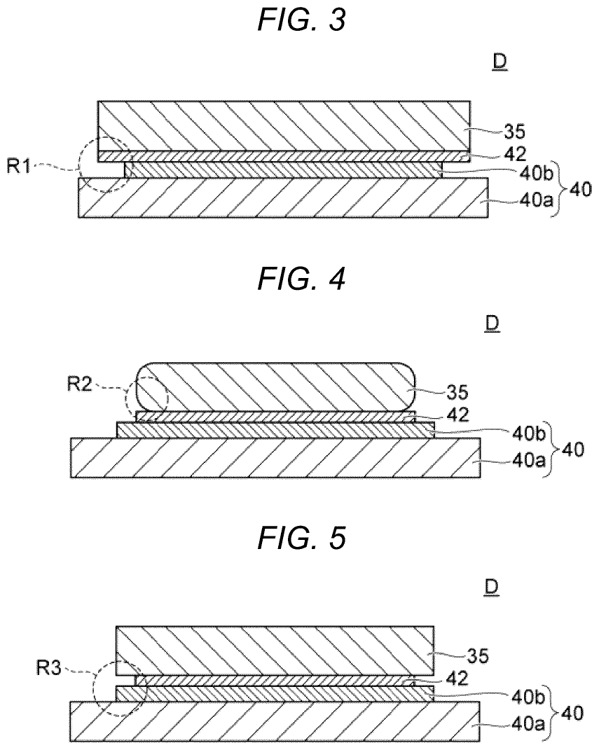

FIG. 3 is an enlarged view of region D in FIG. 2.

As shown in FIG. 3, the semiconductor device 40 includes a semiconductor element 40a and electrode part 40b disposed on the upper surface of the semiconductor element 40a. Although omitted from specific depiction in FIG. 3, a emitter layer can be also disposed on the upper surface of the semiconductor element 40a, similarly, a collector layer can be disposed on the lower surface of the semiconductor element 40a and a gate wiring can be disposed on the side of the emitter layer. The electrode part 40b comprises, for example, aluminum.

The upper surface of the electrode part 40b is smaller in area than the lower surface of the metal plate 35. In particular, the ratio of the area (S1) of the lower surface of the metal plate 35 to the area (S2) of the upper surface of the electrode part 40b preferably satisfies the relationship 1<S1/S2≤1.25.

A metal sintered layer 42 is disposed between the metal plate 35 and the electrode part 40b. The metal sintered layer 42 is pressure sintered to join the metal plate 35 to the electrode part 40b. The metal sintered layer 42 comprises, for example, a silver sintered body.

In the semiconductor device 1 according to the present embodiment, the lower surface of the metal plate 35 is larger than the upper surface of the electrode part 40b as shown by the region R1, and thus the peripheral edge of the metal plate 35 does not press against the electrode part 40b via the metal sintered layer 42. If the surface of metal plate 35 were smaller than the electrode part 40b, the peripheral edge of the metal plate 35 would press into the electrode part 40b via the metal sintered layer 42, which might damage the electrode part 40b. For semiconductor device 1 according to the present embodiment it is possible to avoid such damage to the electrode 40b.

### Modification 1

A first modification of the semiconductor device 1 will be described with reference to FIG. 4. FIG. 4 is an enlarged view of region D in a semiconductor device 1 according to the first modification.

In the semiconductor device 1 according to the first modification, as shown by the region R2, the periphery of the metal plate 35 in plan view is chamfered, beveled, or rounded. Specifically, the peripheral edge of the metal plate 35 in this example is R-chamfered so as to be rounded with a curvature radius R≥0.05 mm. As another example, the peripheral edge of the metal plate 35 may be C-chamfered at C≥0.05 mm.

In the semiconductor device 1 according to this first modification, the peripheral edge of the metal plate 35 is rounded as shown in the region R2, and thus the peripheral edge of the metal plate 35 does not press into the electrode part 40b via the metal sintered layer 42.

If the peripheral edge of the metal plate 35 is not chamfered or rounded in this manner, the peripheral edge of the metal plate 35 would press into the electrode part 40b via the metal sintered layer 42, and the electrode part 40b might thus be damaged. Therefore, the semiconductor device 1 according to the first modification can avoid damage to the electrode part 40b by having the above-described configuration.

### Modification 2

A second modification of the semiconductor device 1 will be described with reference to FIG. 5. FIG. 5 is an enlarged view of region D in the semiconductor device 1 according to the second modification.

In the semiconductor device 1 according to the second modification, the upper surface and the lower surface of the metal sintered layer 42 is smaller in size than the lower surface of the metal plate 35 and also the upper surface of the electrode part 40b in plan view. Specifically, the ratio of the area (S1) of the lower surface of the metal plate 35 to the area (S3) of the upper surface (or lower surface) of the metal sintered layer 42 preferably satisfies the relationship 1<S1/S3≤1.25. The ratio of the area S2 of the upper surface of the electrode part 40b to the area S3 of the upper surface (or lower surfaces) of the metal sintered layer 42 preferably satisfies the relationship: 1<S2/S3≤1.25.

In the semiconductor device 1 according to the second modification, as shown by the region R3, the metal sintered layer 42 is smaller in planar area than the lower surface area of the metal plate 35 and the upper surface area of the electrode part 40b. Thus, the peripheral edge of the metal plate 35 does not press into the electrode part 40b via the metal sintered layer 42. If the planar area of the metal sintered layer 42 were substantially equal to or larger than the area of the lower surface of the metal plate 35 or the upper surface of the electrode part 40b, the peripheral edge of the metal plate 35 could press into the electrode part 40b via the metal sintered layer 42 and damage the electrode part 40b. As described above, the semiconductor device 1 according to the second modification avoids such damage to the electrode part 40b.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A press contact type semiconductor device, comprising:
a first electrode;
a second electrode spaced from the first electrode in a first direction;
a first metal plate between the first electrode and the second electrode in the first direction;
a second metal plate between the first electrode and the second electrode in the first direction;
a semiconductor element between the first and second metal plates in the first direction, the semiconductor element including a semiconductor part with an electrode part on a first surface of the semiconductor part facing towards a second surface of the first metal plate; and
a metal sintered layer between the first metal plate and the electrode part in the first direction, wherein
a planar surface area of a surface of the electrode part facing the first metal plate is less than a planar surface area of the second surface of the first metal plate.

2. The press contact type semiconductor device according to claim 1, wherein the metal sintered layer covers the entire second surface of the first metal plate.

3. The press contact type semiconductor device according to claim 1, wherein the first metal plate and the second metal plate are molybdenum.

4. The press contact type semiconductor device according to claim 1, wherein the semiconductor element is an injection enhanced gate transistor.

5. The press contact type semiconductor device according to claim 1, wherein the semiconductor element is a fast recovery diode.

6. The press contact type semiconductor device according to claim 1, wherein the ratio of the planar surface area of the second surface of the first metal plate to the planar surface area of the surface of the electrode part facing the first metal plate is greater than one but less than or equal to 1.25.

7. The press contact type semiconductor device according claim 1, further comprising:
a cylindrical housing; and
a resin frame in the housing to hold plurality of semiconductor elements.

8. The press contact type semiconductor device according to claims 7, wherein the resin frame has a rectangular lattice shape and holds semiconductor elements in each rectangle of the rectangular lattice shape.

9. A press contact type semiconductor device, comprising:
a first electrode;
a second electrode spaced from the first electrode in a first direction;
a first metal plate between the first electrode and the second electrode in the first direction;
a second metal plate between the first electrode and the second electrode in the first direction;
a semiconductor element between the first and second metal plates in the first direction, the semiconductor element including a semiconductor part with an electrode part on a first surface of the semiconductor part facing towards a second surface of the first metal plate; and
a metal sintered layer between the first metal plate and the electrode part in the first direction, wherein
an outer peripheral edge of the second surface of the first metal plate is chamfered.

10. The press contact type semiconductor device according to claim 9, wherein an outer peripheral edge of a surface of the second metal plate is chamfered.

11. The press contact type semiconductor device according to claim 9, wherein the chamfer of the outer peripheral edge of the second surface of the first metal plate is a rounding.

12. The press contact type semiconductor device according to claim 9, wherein an outer peripheral portion of the metal sintered layer does not contact the first metal plate.

13. The press contact type semiconductor device according to claim 9, wherein a planar surface area of a surface of the electrode part facing the first metal plate is greater than a planar surface area of a surface of the metal sintered layer contacting electrode part.

14. The press contact type semiconductor device according to claim 13, wherein a planar surface area of the first surface is greater than the planar surface area of the surface of the electrode part facing the first metal plate.

15. The press contact type semiconductor device according to claim 9, wherein
the first and second metal plates are molybdenum,
the metal sintered layer is a silver sintered body, and
the semiconductor element comprises a silicon substrate.

16. The press contact type semiconductor device according claim 9, further comprising:
a cylindrical housing; and
a resin frame in the housing to hold plurality of semiconductor elements.

17. The press contact type semiconductor device according to claims 16, wherein the resin frame has a rectangular lattice shape and holds semiconductor elements in each rectangle of the rectangular lattice shape.

18. A press contact type semiconductor device, comprising:
a first electrode;
a second electrode spaced from the first electrode in a first direction;
a first metal plate between the first electrode and the second electrode in the first direction;
a second metal plate between the first electrode and the second electrode in the first direction;
a semiconductor element between the first and second metal plates in the first direction, the semiconductor element including a semiconductor part with an electrode part on a first surface of the semiconductor part facing towards a second surface of the first metal plate; and
a metal sintered layer between the first metal plate and the electrode part in the first direction, wherein
the metal sintered layer does not extend to an outer peripheral edge of the electrode part, and
the metal sintered layer does not cover an outer peripheral portion of the second surface of the first electrode.

19. The press contact type semiconductor device according claim 18, further comprising:
a cylindrical housing; and
a resin frame in the housing to hold plurality of semiconductor elements.

20. The press contact type semiconductor device according to claims 19, wherein the resin frame has a rectangular lattice shape and holds semiconductor elements in each rectangle of the rectangular lattice shape.
